(19) United States
(12) Patent Application Publication
(10) Pub. No.: US 2010/0255181 A1
(43) Pub. Date: Oct. 7, 2010

(54) VAPOUR DELIVERY SYSTEM

(76) Inventor: Fred Hopper, Maidenhead (GB)

Correspondence Address: Manelli Denison & Selter PLLC;Attn:William H. Bollman, 2000 M Street, NW, 7th Floor, Washington, DC, 20036, US

(21) Appl. No.: 12/733,792

(22) PCT Filed: Sep. 25, 2008
(86) PCT No.: PCT/GB2008/003257

§ 371 Date: Mar. 19, 2010

(30) Foreign Application Priority Data
Sep. 25, 2007 (GB) 0718686.9

(51) Int. Cl. C23C 16/52; B05C 11/00

(52) U.S. Cl. 427/8; 118/688; 118/692

(57) ABSTRACT

A delivery system (10) for delivering species (12) to a processing chamber (14), so as to coat the surface of a large item, thereby imparting specific properties thereto, comprises: a species container (16) for containing species supplied from a source (18) of liquid species; evaporation means (20) for evaporating liquid species in said container; flow guide means (22, 24) for guiding flow of evaporated species to a processing chamber; and monitoring means (28) for measuring a rate over time of evaporation of species from said container so that flow of evaporated species delivered to said processing chamber can be monitored.

### FIELD OF THE INVENTION

This invention relates to a delivery system and method for delivering species to a processing chamber, and to an apparatus for plasma processing of a surface of an item, comprising such a delivery system.

### BACKGROUND OF THE INVENTION

Delivery systems are hereto known for delivering and metering vapour from a high boiling-point liquid into a vacuum chamber, in order to carry out a chemical or physical process within the vacuum chamber. Such known systems are not well suited to the case in which the liquid is a chemically reactive monomer.

In a known bubbler system, carrier gas bubbles through the liquid, absorbing and transporting the vapour into the vacuum chamber. In a known evaporator system, a sufficiently high vapour pressure is generated (of the order of around 1 Torr) to deliver the vapour via a mass flow controller into the vacuum chamber. In a vapour delivery system, liquid is heated and drawn through a fine orifice, typically assisted by a carrier gas.

Bubbler and vapour delivery systems suffer from the disadvantage that a flow of carrier gas is required, and therefore restrictions are placed on the available range of vapour/carrier composition. Evaporator systems have the drawback that the liquid must be heated to a sufficiently high temperature in order to generate a sufficiently high pressure to enable a mass flow controller to function. Such high temperature evaporator systems suffer from attendant risks of instability, including the risk of polymerisation in the case that the liquid is a monomer.

Another problem suffered by vapour delivery systems is that they are prone to blockage of the fine orifice, either by particulate contamination, in the liquid, or as a result of a tendency to polymerise, in the case that the liquid is a monomer.

### PRIOR ART

Published International Patent Application WO-A3-2006/057708 (Tokyo Electron limited) describes a measurement system for determining flow rate of low vapour pressure precursors that are employed in multi-layer metallisation structures that are required in the fabrication of integrated circuits (IC). One example of a low vapour pressure precursor is ruthenium, which is deposited in the form of ruthenium carbonyl (Ru₃(CO)₁₂). Ruthenium is used as a barrier layer due to its good adhesive and barrier properties.

The apparatus described is specifically for use in the production of semiconductor micro circuits—so called very large scale integrated (VLSI) circuits—and describes a chamber with a substrate holder, a heater, a vapour distribution system for introducing a metal precursor and a flow measurement system.

Another example of a monomer delivery system is described in Published International Patent Application WO-A1-98/10116 (Talison Research), which discloses a system for use as a vapour deposition apparatus. The system includes an ultrasonic atomizer which in use is disposed in a reaction chamber.

Both the aforementioned disclosures describe solutions to well known problems associated with the fabrication of semiconductors and other similar devices. Neither system is suitable for the coating of larger items, such as, for example, household items, and items of clothing or footwear, paper goods or consumer products such as electronic items.

An object of the present invention is to provide an apparatus for delivering a species to a chamber for the purposes of imparting specific properties to large items in the chamber or passing therethrough.

The term large item is intended to include such things as, for example: sports equipment, fabrics and similar, materials, paper products and synthetic plastics goods, clothing, high value fashion items and accessories, footwear, electrical goods, personal electronic devices, mobile telephones, pagers, personal digital assistants (PDAs) and MP3 devices.

### SUMMARY OF THE INVENTION

According to a first aspect of the present invention there is provided a delivery system for delivering a species to a processing chamber, within which, in use, at least one large item is located for the purposes of having one or more properties imparted to the surface(s) thereof, the system comprising:

a species container for containing species supplied from a source of liquid species;

evaporation means for evaporating liquid species in said container;

flow guide means for guiding flow of evaporated species to the processing chamber; and

monitoring means for measuring a rate over time of evaporation of species from said container so that flow of evaporated species delivered to said processing chamber can be monitored.

Ideally the entire surface of the large item(s) is coated. Preferably the coating provides at least one of the following properties to the large item, the properties including: waterproof coating, fire resistant coating, antiseptic coating, coloured coating, hardened coating and ultraviolet (UV) resistant coating.

The present invention also provides a method of delivering species to a processing chamber, the method comprising:

supplying liquid species from a source of species to a container;

evaporating liquid species from said container;

guiding flow of evaporated species to a processing chamber; and

measuring a rate over time of evaporation of species from said container so that flow of evaporated species delivered to said processing chamber can be monitored.

The present invention also provides apparatus for plasma processing of a surface of an item, the apparatus comprising:

a processing chamber into which an item can be placed;

a delivery system for delivering a species to the processing chamber for forming a plasma in said chamber;

means for generating an electrical field internally of the processing chamber for forming a plasma when said species is supplied thereto so that a surface of said item can be processed; and

pressure control means for selectively controlling pressure in the processing chamber;

wherein said delivery system comprises:

a species container for containing species supplied from a source of liquid species;

evaporation means for evaporating liquid species in said container;

flow guide means for guiding flow of evaporated species to the processing chamber; and

monitoring means for measuring a rate over time of evaporation of species from said container so that flow of evaporated species delivered to said processing chamber can be monitored.

Other preferred and/or optional features of the invention are defined in the accompanying claims.

The invention will now be described, by way of example only, with reference to the accompanying drawings, in which:—

### BRIEF DESCRIPTION OF THE DRAWINGS

FIG. 1 is a schematic representation of a delivery system for delivering species to a processing chamber;

FIG. 2 is a graph showing change in mass of liquid species in a container as shown in FIG. 1; and

FIG. 3 shows two graphs of a rate of change of mass of liquid species in two containers of different size.

### DETAILED DESCRIPTION OF THE ILLUSTRATED EMBODIMENTS

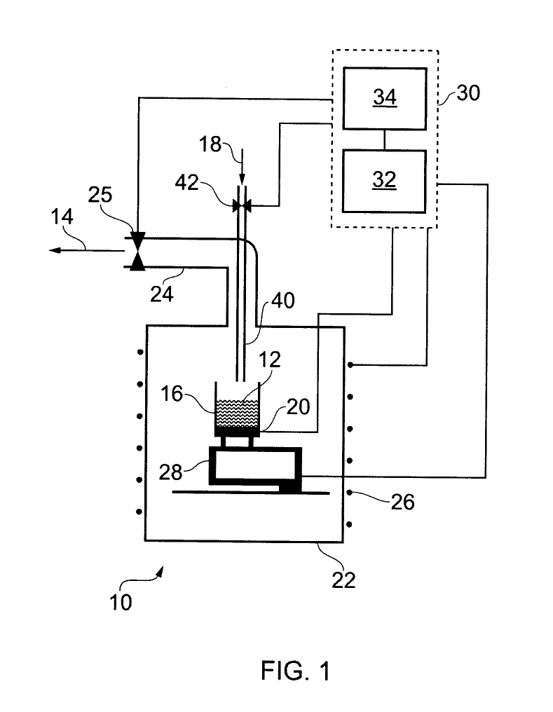

Referring to FIG. 1, a delivery system 10 is shown for delivering species 12 to a processing chamber 14. The system comprises a species container 16 for containing species supplied from a source 18 of liquid species. The container 16 may be a flask or beaker, or other vessel for containing liquid to be evaporated and is preferably open, that is not sealed, to facilitate the supply of liquid to the container 16 and the evaporation of liquid from the container 16.

Evaporation means 20, which may be a resistive, infra red or other heating means, is provided for evaporating the liquid species 12 when it is in the container. The liquid species in the container can be heated as shown in FIG. 1 to promote evaporation. In an alternative embodiment the heating means may comprise a heated plate or if the container is conductive, by induction of heat in the container.

The heat required to achieve required evaporation is a function of a number of different factors. These factors include: pressure in the surrounding region above the liquid, and the concentration of species and other constituents in the region; temperature of the liquid; inter-molecular forces in the liquid; and surface area of the liquid. Some of these other factors, such as pressure, can also be used to control evaporation, but changes in a rate of evaporation is more sensitive to changes in supplied heat than changes in pressure.

The inter-molecular forces in the liquid are constant for each species and the surface area is constant for a selected container of a particular size and shape. The pressure required for a given processing step is also generally constant, subject to some fluctuation. Therefore, the amount of heat provided to the liquid species in order to achieve a required flow of species into the processing chamber can be determined either by calculation or by experimentation. Such a predetermined characteristic response of the species 12 to activation of the evaporation means 20 can be determined for a plurality of species and for a plurality of processing steps to be conducted in the processing chamber and the evaporation means can be controlled to achieve the required rate of evaporation. More specifically, the amount of heat supplied by the evaporation means to the container in order to achieve a required evaporation rate can be predetermined.

The system 10 comprises flow guide means 22, 24 for guiding flow of evaporated species to the processing chamber 14. The flow guide means in FIG. 1 comprises an evaporation chamber 22 into which species can be evaporated from container 16 and a conduit 24 for selective fluid connection between the evaporation chamber and the processing chamber so that species can be selectively delivered from said evaporation chamber to said processing chamber. The conduit 24 comprises a valve 25 for controlling selective fluid connection between said chamber and said processing chamber. Evaporation chamber 22 and conduit 24 may comprise additional heating means 26 for reducing condensation of species which has been evaporated from the container 16 when it contacts an internal surface of the evaporation chamber and the conduit.

Monitoring means 28 measures a rate over time of evaporation of species 12 from the container 16 so that flow of evaporated species delivered to the processing chamber 14 can be monitored. The monitoring means 28 may comprise means for measuring a change in weight (or mass) of liquid species in said container over time, as shown in FIG. 1. A change in weight is a measure of the weight or mass of species which has been evaporated from the container 16 and delivered to the processing chamber. Suitable weighing means includes a load cell, a balance or a strain gauge.

Alternatively, or additionally, the monitoring means 28 may comprise a level sensor for sensing a level of species in the container, such as an ultrasonic, optical or capacitive sensor.

With reference to FIG. 1, a change in weight of liquid species during a delivery cycle is indicative of the flow of evaporated species delivered to the processing chamber. It can therefore be determined by measuring such a change of weight if a correct flow of evaporated species has entered the processing chamber. If a correct flow is determined to have entered the processing chamber then, it can also be determined that processing has been carried out successfully. If an incorrect flow is determined to have entered the processing chamber 14 then, it can be determined that processing has not been carried out successfully, or at least not to a desired or required standard.

A determination of how successful or unsuccessful processing has been, can be made by a comparison between the expected change in weight for a delivery and the real time monitored change in weight. If the monitoring means 28 has a display showing weight, then such a determination can be made simply by manually, or automatically, comparing a monitored change of weight with a look up table.

Alternatively and as shown in FIG. 1, the predetermined characteristic rate of evaporation for one or more species for use in one or more processing steps can be stored in a memory 32, such as an electronic memory, of a control means 30. Monitoring means 28 is adapted to supply a signal relating to the monitored rate of evaporation to control means 30. In this alternative, the control means 30 ideally includes a comparator means 34 for comparing the monitored rate of evaporation received from the monitoring means with the predetermined characteristic rate of evaporation stored in the memory. In one embodiment the comparator means is arranged to emit a signal based on its comparison of the monitored and predetermined rates.

In the arrangement shown in FIG. 1, the control means 30 is responsive to the signal emitted from said comparator means and can control activation of said evaporation means so that the actual rate of flow of species is adjusted to conform with said predetermined characteristic rate, for example by way of a feedback loop which varies the temperature of the heater.

A monitored change of weight may not be consistent with a predetermined rate, if pressure in the evacuation chamber 22 is different from a pressure when the characteristic rate is determined. The pressure may vary because of operation of a vacuum pumping means, or due to other variables within the system. Such changes in pressure can be compensated for in the delivery system 10.

As shown in FIG. 1, control means 30 is operably connected to valve 25 so it can control fluid connection between said evacuation chamber 22 and said processing chamber 14 so that delivery of species from the evacuation chamber to said processing chamber can be controlled. The rate of delivery of evaporated species to the processing chamber is achieved by controlling the rate of evaporation, and valve 25 is controlled to turn the delivery “off” or “on”.

A supply conduit 40 selectively supplies liquid species to the container 16 by operation of valve 42. The control means 30 may be operably connected to valve 42 as shown in FIG. 1 so that it can control supply of liquid species to the container 16.

One method of operation of the system, shown in FIG. 1, will now be described.

The evacuation chamber is vented to atmospheric pressure by an aperture (not shown). The evacuation chamber 22 and container 16 are isolated from the processing chamber 14 by closing valve 25 in conduit 24. Valve 42 is opened and a liquid species, such ‘PFAC 8’ or any perfluorinated chemical with an active end or side group, is supplied along conduit 40 from source 18 while the system is at atmospheric pressure. The quantity of liquid species supplied is determined by a processing step to be carried out in the processing chamber, and in this regard, a discrete quantity of liquid can be supplied for a discrete processing step or sufficient liquid can be supplied for more than one processing steps. When a required quantity of species has been supplied to container 16, valve 42 is closed and valve 25 is opened. A vacuum pumping arrangement connected to the processing chamber evacuates gas in the evacuation chamber 22 and conduit 24 to achieve a required processing pressure. Valve 25 in conduit 24 may be closed once evacuation chamber 22 has been evacuated.

Evaporation means 20 heats the container 16 to promote evaporation. The amount of heat energy supplied to the container is controlled to adjust and maintain evaporation of species from the container at the desired rate. When processing is required, valve 25 is opened and evaporated species is caused to flow through conduit 24 and into processing chamber 14 because of a pressure differential generated by the vacuum pumping arrangement.

During delivery of species, the evacuation chamber 22 and conduit 24 are heated by heater 26 to reduce condensation on their internal surfaces.

The monitoring means 28 transmits a signal to the comparator means 34 in accordance with a measured rate of evaporation of species from container 16. The comparator means compares the measured rate of evaporation received from the monitoring means 28 with a predetermined characteristic (or desired) rate of evaporation stored in memory 32. The comparator means 34 emits a signal relating to the difference in monitored evaporation rate and the predetermined rate. The control means 30 controls the evaporation means 20 to control the heat supplied to the container 16 in order to control the rate of evaporation so that actual rate of evaporation is adjusted if required to conform with the predetermined rate of evaporation.

Control means 30 is shown in FIG. 1, but in a delivery system without such control means a change in mass of species in container 16 can be monitored and if the change in mass is not as predetermined, it can be determined that an incorrect amount of species has entered the processing chamber 14 and therefore a processing step is not completed adequately.

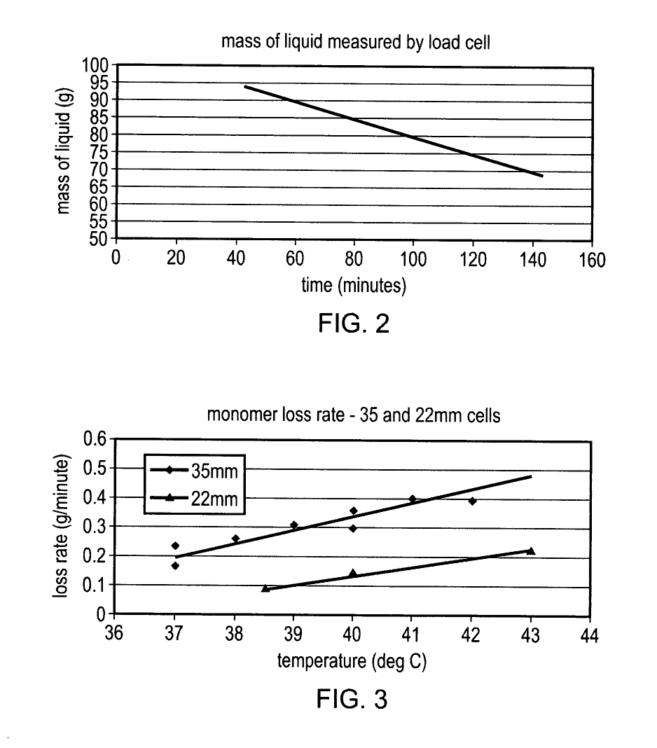

Evaporation of liquid species is monitored by measuring a change in mass over time of liquid in the container 16. FIG. 2 shows a typical graph of change in mass over time. In the example shown, the delivery of species is determined to be linear over time and the gradient of the graph is a measure of the flow of species into the processing chamber.

FIG. 3 shows a rate of loss of species over time for two selected containers with a diameter of 35 mm and 22 mm.

As shown in the graph for the 35 mm container the loss rate is linear and the measured rate of delivery is as required for a processing step.

The system is suitable for delivering a monomer for use in plasma processing to a processing chamber. Such a monomer may be required for plasma deposition of a surface of an item in the processing chamber, and may be monomer for achieving a thin hydrophobic polymerised layer on an item.

Unlike prior art delivery systems, in the system described with reference to FIG. 1, a carrier gas is not required to deliver species to the processing chamber and therefore vapour composition is not restricted. A mass flow controller is not required. The pressure of vapour in contact with the liquid species in container 16 is only marginally higher than that throughout the processing chamber, thus minimising the required temperature elevation of the liquid. Also, the aperture size of conduit 24 may be in the region of several centimetres reducing the propensity of the passage to blockage.

The invention has been described by way of three embodiments, with modifications and alternatives, but having read and understood this description further embodiments and modifications will be apparent to those skilled in the art. All such embodiments and modifications are intended to fall within the scope of the present invention as defined in the accompanying claims.

Further items that may be coated with a water proof/water repellent coating include: sports equipment, high value fashion items such as fashion accessories, electrical goods, personal electronic devices such as BLUETOOTH (Trade Mark) devices, mobile telephones, pagers, personal digital assistants (PDAs), MP3 devices, electrical cables, compact discs (CDs), laptops and keyboards.

It will be appreciated that the invention may be used in conjunction with a range of different activated species in dependence upon the desired characteristics and properties of the item to be coated, and in order to achieve a desired technical effect.

Thus, for example, an antiseptic species may be introduced in order to provide an antiseptic coating, in or on such items as: bandages, dressings, and emergency medical equipment; specialised items of furniture, bathroom furniture, first aid kits, items of clothing; and medical, surgical and dental devices.

Alternatively a fire retardant species can be introduced in order to provide fire resistant properties to such items as: items of clothing, leather, fabric materials and covers, paper goods, electrical goods, personal electronic devices such as BLUETOOTH (Trade Mark) devices mobile telephones, pagers, personal digital assistant (PDA), MP3 devices, electronic cables, compact discs (CDs), banknotes and credit cards.

In a yet further embodiment, the species to be introduced is a protein binder which is adapted to be introduced into bone and dental implants in order to promote bone growth and binding of a bone material, thereby enhancing re-growth/repair of broken bones or teeth.

In a further embodiment, the species to be introduced may be an electrically conductive material which is adapted to be introduced into specific areas/regions of the item to be coated.

It will be appreciated that the invention is adapted to coat stitched, seamed, woven or connected fabrics or materials, such as, for example: leathers and shoe uppers with or without a bonded sole.

It is also within the scope of the present invention to multiply coat items with two or more different species, so as to provide two or more different effects, such as for example imparting waterproof and fireproof properties to an item.

The invention has been described by way of various examples and embodiments, with modifications and alternatives, but having read and understood this description, further embodiments and modifications will be apparent to those skilled in the art. All such embodiments and modifications are intended to fall within the scope of the present invention as defined in the accompanying claims

1. A delivery system for delivering a species to a processing chamber, within which, in use, at least one large item is located for the purposes of having one or more properties imparted to the surface(s) thereof, the system comprising:
a species container for containing species supplied from a source of liquid species;
evaporation means for evaporating liquid species in said container;
flow guide means for guiding flow of evaporated species to the processing chamber; and
monitoring means for measuring a rate over time of evaporation of species from said container so that flow of evaporated species delivered to said processing chamber can be monitored.

2. A delivery system as claimed in claim 1, wherein said species is a monomer for use in plasma processing.

3. A delivery system as claimed in claim 1 or 2, wherein said evaporation means comprises heating means for heating liquid species in the container.

4. A delivery system as claimed in any preceding claim, wherein said flow guide means comprises an evaporation chamber into which species can be evaporated from said container and a conduit for selective fluid connection between said evaporation chamber and said processing chamber so that species can be selectively delivered from said evaporation chamber to said processing chamber.

5. A delivery system as claimed in claim 4, wherein said conduit comprises a valve for controlling selective fluid connection between said chamber and said processing chamber.

6. A delivery system as claimed in any preceding claim, wherein said flow guide means comprises heating means for reducing condensation of species on an internal surface thereof.

7. A delivery system as claimed in any preceding claim, wherein said monitoring means comprises weighing means for measuring a change in weight of liquid species in said container over time.

8. A delivery system as claimed in claim 7, wherein said weighing means comprises a load cell thermally insulated from the container.

9. A delivery system as claimed in any of claims 1 to 6, wherein said monitoring means comprises a level sensor for sensing a level of species in said container.

10. A delivery system as claimed in any preceding claim, comprising control means configured according to a predetermined characteristic response of said species to evaporation by said evaporation means so that a rate of delivery of said species can be controlled in accordance with a required plasma process to be performed in said processing chamber.

11. A delivery system as claimed in claim 10 when claim 10 is dependent on claim 4 or any preceding claim which is dependent on claim 4, wherein said control means controls fluid connection between said evacuation chamber and said processing chamber so that delivery of species from the evacuation chamber to said processing chamber can be controlled.

12. A delivery system as claimed in any preceding claim, comprising a supply conduit for selectively supplying liquid species to said container.

13. A delivery system as claimed in claim 12 when claim 12 is dependent on claim 10 or any preceding claim which dependent on claim 10, wherein said control means can control supply of liquid species to said container.

14. A delivery system as claimed in any preceding claim, comprising comparator means for comparing a monitored rate of evaporation of species from said container with a predetermined characteristic rate of evaporation and emitting a signal relating to a difference between said monitored rate and said predetermined characteristic rate.

15. A delivery system as claimed in claim 14, wherein said control means is responsive to said signal emitted from said comparator means and can control activation of said evaporation means so that monitored rate is adjusted to conform with said predetermined characteristic rate.

16. A method of delivering species to a processing chamber, the method comprising:
supplying liquid species from a source of species to a container;
evaporating liquid species from said container;
guiding flow of evaporated species to a processing chamber; and
monitoring a rate over time of evaporation of species from said container so that a metered flow of evaporated species can be delivered to said processing chamber.

17. A method as claimed in claim 16, wherein said species is a monomer for use in plasma processing.

18. A method as claimed in claim 16 or 17, wherein said liquid species is evaporated from said container by heating said species.

19. A method as claimed in any preceding claim, wherein said species is selectively delivered to said processing chamber when species is required in said processing chamber for processing.

20. A method as claimed in any of claims 16 to 19, wherein evaporation of species is monitored by measuring a change in weight of liquid species in said container over time.

21. A method as claimed in any of claims 16 to 20, wherein evaporation of species is monitored by measuring a change in level of liquid species in said container over time.

22. A method as claimed in any of claims 16 to 21, wherein heat is supplied to said liquid species in accordance with a predetermined characteristic response of said species to supply of heat so that a rate of delivery of said species can be controlled in accordance with a required plasma process to be performed in said processing chamber.

23. A method as claimed in any of claims 16 to 22, wherein a monitored rate of evaporation of species from said container is compared with a predetermined characteristic rate of evaporation so that a difference between said monitored rate and said predetermined characteristic rate can be determined.

24. A method as claimed in claim 23, wherein evaporation of said species is controlled in accordance with said difference between said monitored rate and said predetermined characteristic rate and is adjusted so that said monitored rate conforms with said predetermined characteristic rate.

25. Apparatus for plasma processing of a surface of an item, the apparatus comprising:
a processing chamber into which an item can be placed;
a delivery system for delivering a species to the processing chamber for forming a plasma in said chamber;
means for generated an electrical field internally of the processing chamber for forming a plasma when said species is supplied thereto so that a surface of said item can be processed; and
pressure control means for selectively controlling pressure in the processing chamber;
wherein said delivery system comprises:
a species container for containing species supplied from a source of liquid species;
evaporation means for evaporating liquid species in said container;
flow guide means for guiding flow of evaporated species to the processing chamber; and
monitoring means for measuring a rate over time of evaporation of species from said container so that flow of evaporated species delivered to said processing chamber can be monitored.

26. Apparatus as claimed in claim 25, wherein said delivery system is as claimed in any of claims 1 to 15.
